(19) United States
(12) Patent Application Publication
(10) Pub. No.: US 2009/0166677 A1
(43) Pub. Date: Jul. 2, 2009

(54) SEMICONDUCTOR DEVICE AND MANUFACTURING METHOD THEREOF

(76) Inventors: Daisuke SHIBATA, Osaka (JP); Tatsuo Morita, Kyoto (JP); Manabu Yanagihara, Osaka (JP); Yasuhiro Uemoto, Shiga (JP)

Correspondence Address: MCDERMOTT WILL & EMERY LLP, 600 13TH STREET, NW, WASHINGTON, DC, 20005-3096, US

(21) Appl. No.: 12/329,939

(22) Filed: Dec. 8, 2008

(30) Foreign Application Priority Data
Dec. 28, 2007 (JP) 2007-339141

(51) Int. Cl. H01L 21/338; H01L 29/812

(52) U.S. Cl. 257/192; 438/172; 257/E29.317; 257/E21.452

(57) ABSTRACT

A semiconductor device includes: a semiconductor substrate; a diode having a cathode formed on a first surface side of the semiconductor substrate and an anode formed on a second surface side of the semiconductor substrate; and a transistor formed over the semiconductor substrate. The transistor includes a semiconductor layer laminate formed over the semiconductor substrate, a source electrode and a drain electrode that are formed spaced apart from each other over the semiconductor layer laminate, and a gate electrode formed between the source electrode and the drain electrode. The source electrode is electrically connected to the anode, and the drain electrode is electrically connected to the cathode.

### CROSS-REFERENCE TO RELATED APPLICATIONS

This application claims priority under 35 U.S.C. §119(a) on Japanese Patent Application No. 2007-339141 filed on Dec. 28, 2007, the entire contents of which are hereby incorporated by reference.

### BACKGROUND OF THE INVENTION

1. Field of the Invention

The present invention relates to a semiconductor device and a manufacturing method thereof. More particularly, the present invention relates to a nitride semiconductor device for use in a power supply circuit or the like, and a manufacturing method thereof.

2. Related Art

Nitride semiconductors such as gallium nitride (GaN), aluminum nitride (AlN), and indium nitride (InN) are wide-gap semiconductors having a wide bandgap. For example, GaN and AlN have a bandgap of 3.4 eV and 6.2 eV at room temperature, respectively. Nitride semiconductors are characterized by their higher breakdown field and higher saturated electron drift velocity than those of other compound semiconductors such as gallium arsenide (GaAs), silicon semiconductors, or the like.

Nitride semiconductors form various multi-element compounds represented by the general formula: AlₓGa_{y}In_{1-x-y}N (where 0≦x≦1, 0≦y≦1, x+y≦1). The use of multi-element compounds having different bandgaps therefore facilitates formation of a hetero structure. For example, in a hetero structure of aluminum gallium nitride (AlGaN) and gallium nitride (GaN), charges are generated on a (0001) heterointerface by spontaneous polarization and piezoelectric polarization, and a sheet carrier concentration of 1×10¹³ cm⁻² or more is obtained even in an undoped state. A high current density hetero-junction field effect transistor (HFET) can therefore be implemented by using a two-dimensional electron gas (2DEG) at a heterointerface.

Nitride semiconductors are advantageous to implement a higher power, a higher breakdown voltage, and the like. Nitride semiconductors therefore enable reduction in on-state resistance of a high breakdown-voltage power transistor. For example, in the field of high breakdown voltage power transistors having a breakdown voltage of 200 V or more, the on-state resistance has been reduced to 1/10 of Si-based MOSFETs (Metal-Oxide-Semiconductor Field Effect Transistors) and ⅓ or less of IGBTs (Insulated Gate Bipolar Transistors) (e.g., see W. Saito et al., “IEEE Transactions on Electron Devices,” 2003, Vol. 50, No. 12, p. 2528).

### SUMMARY OF THE INVENTION

However, it has been found that there are the following problems when a nitride semiconductor HEFT is applied to an inverter or the like.

When an inductive load is connected, energy (E=1/2LI², where L is self-inductance and I is a current) accumulated in the inductive load needs to be consumed within a circuit when turned off.

A silicon MOSFET has a parasitic diode connected antiparallel between the drain and the source in a device structure (a cathode is connected to the drain and an anode is connected to the source). When the silicon MOSFET is turned off, energy from an inductive load can be consumed by using an avalanche region of the parasitic diode. The silicon MOSFET therefore has a relatively high avalanche resistance.

Note that the term “avalanche resistance” is an index of breakdown resistance of a device and is defined as the maximum energy in an inductive load which can be consumed by the device without causing breakdown of the device.

An HFET, on the other hand, does not have a parasitic diode structure and cannot actively consume energy from an inductive load. The HFET therefore has a low avalanche resistance, and it is difficult to turn off the HFET by an inductive load having a large self-inductance L. It is therefore necessary to increase the avalanche resistance by externally providing a diode.

However, externally providing a diode increases the number of parts and also increases the occupied area, which is not preferable for semiconductor devices for which reduction in size and cost has been demanded.

The present invention is made to solve the above problems and it is an object of the present invention to implement a nitride semiconductor device having a high avalanche resistance while suppressing increase in the number of parts and increase in occupied area caused by externally providing a diode.

In order to achieve the above object, according to the present invention, a transistor is formed over a substrate having a diode formed therein, whereby the diode and the transistor are formed integrally.

More specifically, a first semiconductor device according to the present invention includes: a semiconductor substrate; a diode having a cathode formed on a first surface side of the semiconductor substrate and an anode formed on a second surface side of the semiconductor substrate; and a transistor formed over the semiconductor substrate. The transistor includes a semiconductor layer laminate including a first nitride semiconductor layer and a second nitride semiconductor layer that are formed sequentially from the semiconductor substrate side. The second nitride semiconductor layer has a wider bandgap than that of the first nitride semiconductor layer. The transistor further includes a source electrode and a drain electrode that are formed spaced apart from each other over the semiconductor layer laminate, and a gate electrode formed between the source electrode and the drain electrode. The source electrode is electrically connected to the anode, and the drain electrode is electrically connected to the cathode.

According to the first semiconductor device, the occupied area of the semiconductor device is approximately equal to the area of the transistor, and there is almost no increase in area of the semiconductor device by the diode. Since the source electrode is electrically connected to the anode and the drain electrode is electrically connected to the cathode, energy of an inductive load is consumed by the diode formed in the semiconductor substrate. The avalanche resistance of the transistor is therefore improved.

A second semiconductor device according to the present invention includes: a semiconductor layer laminate formed over a substrate; a cathode electrode, a source electrode, and a drain electrode that are formed spaced apart from each other over the semiconductor layer laminate; a gate electrode formed between the source electrode and the drain electrode; a first p-type semiconductor layer formed between the cathode electrode and the source electrode; and an anode electrode formed on the first p-type semiconductor layer. The semiconductor layer laminate includes a first nitride semiconductor layer formed over the substrate and a second nitride semiconductor layer formed on the first nitride semiconductor layer and having a wider bandgap than that of the first nitride semiconductor layer. The source electrode and the anode electrode are electrically connected to each other, and the drain electrode and the cathode electrode are electrically connected to each other.

In the structure of the second semiconductor device, the transistor and the diode are formed in the semiconductor layer laminate. Accordingly, there is almost no increase in area of the semiconductor device by the diode. The source electrode and the anode electrode are electrically connected to each other and the drain electrode and the cathode electrode are electrically connected to each other. Therefore, energy of an inductive load can be consumed by the diode, whereby the avalanche resistance of the transistor can be improved.

A method for manufacturing a semiconductor device according to the present invention includes the steps of: (a) preparing a semiconductor substrate having on a first surface side thereof an n-type region that will serve as a cathode of a diode, and having a diffusion prevention layer between the n-type region and the first surface; (b) forming an anode of the diode on a second surface side of the semiconductor substrate; (c) forming over the first surface of the semiconductor substrate a nitride transistor having a channel region in which electrons travel in a direction parallel to the first surface and having a source electrode, a drain electrode, and a gate electrode; and (d) forming a drain via plug electrically connecting the drain electrode and the n-type region to each other; and (e) electrically connecting the source electrode and the anode to each other.

In the manufacturing method of the semiconductor device according to the present invention, Ga or the like can be prevented from diffusing into the semiconductor substrate and thus causing the n-type region to turn into a p-type region during formation of the nitride transistor. Accordingly, a diode can be reliably formed in the semiconductor substrate, whereby a semiconductor device having a high avalanche resistance can be implemented.

### BRIEF DESCRIPTION OF THE DRAWINGS

FIG. 1 is a cross-sectional view of a semiconductor device according to a first embodiment of the present invention;

FIG. 2 is an equivalent circuit diagram of the semiconductor device according to the first embodiment of the present invention;

FIG. 3 is an enlarged cross-sectional view of a side end portion of a semiconductor substrate in the case where the semiconductor device of the first embodiment of the present invention is diced into individual chips;

FIG. 4 is a cross-sectional view of a modification of the semiconductor device according to the first embodiment of the present invention;

FIG. 5 is a cross-sectional view of a modification of the semiconductor device according to the first embodiment of the present invention;

FIG. 6 is a cross-sectional view of a semiconductor device according to a first modification of the first embodiment of the present invention;

FIGS. 7A, 7B, and 7C are cross-sectional views sequentially illustrating the steps of a manufacturing method of the semiconductor device according to the first modification of the first embodiment of the present invention;

FIGS. 8A, 8B, 8C, and 8D are cross-sectional views sequentially illustrating the steps of a modification of the manufacturing method of the semiconductor device according to the first modification of the first embodiment of the present invention;

FIG. 9 is a cross-sectional view of a semiconductor device according to a second modification of the first embodiment of the present invention; and

FIG. 10 is a cross-sectional view of a semiconductor device according to a second embodiment of the present invention.

### DETAILED DESCRIPTION OF THE PREFERRED EMBODIMENTS

### First Embodiment

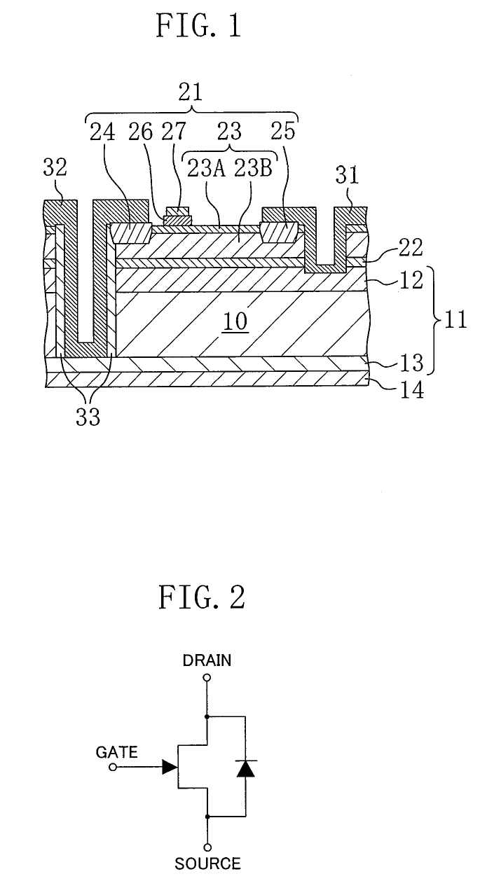

Hereinafter, a first embodiment of the present invention will be described with reference to the figures. FIG. 1 shows a cross-sectional structure of a semiconductor device according to the first embodiment. As shown in FIG. 1, the semiconductor device of the first embodiment includes a semiconductor substrate 10 and a hetero-junction transistor (HFET) 21. The semiconductor substrate 10 is an n-type silicon substrate having a diode 11 formed therein. The HFET 21 is made of a nitride semiconductor and is formed over the semiconductor substrate 10.

The diode 11 is a PIN (p-intrinsic-n) diode and has a cathode 12 formed on a first surface side of the semiconductor substrate 10 and an anode 13 formed on a second surface side of the semiconductor substrate 10. The cathode 12 is an n-type region made of an n-type impurity diffusion layer. The anode 13 is a p-type region made of a p-type impurity diffusion layer and is ohmic-connected to a back electrode 14 formed on the second surface. In this case, the first surface is an element formation surface of the semiconductor substrate, and the second surface is an opposite surface (back surface) to the element formation surface.

The HFET 21 has a semiconductor layer laminate 23, a source electrode 24, a drain electrode 25, and a gate electrode 27. The semiconductor layer laminate 23 is formed on the first surface (element formation surface) of the semiconductor substrate 10 with a buffer layer 22 interposed therebetween. The source electrode 24 and the drain electrode 25 are formed spaced apart from each other in an upper portion of the semiconductor layer laminate 23. The gate electrode 27 is formed on the semiconductor layer laminate 23 with a control layer 26 interposed therebetween. The gate electrode 27 is formed between the source electrode 24 and the drain electrode 25.

The semiconductor layer laminate 23 has an undoped GaN layer 23A of 2 μm thickness and an undoped AlGaN layer 23B of 25 nm thickness that are formed sequentially from bottom. A channel region made of a two-dimensional electron gas (2DEG) is formed in an interface region of the GaN layer 23A with the AlGaN layer 23B.

The source region 24 and the drain electrode 25 are a laminate of titanium (Ti) and aluminum (Al) and are ohmic-connected to the channel region. In this embodiment, in order to reduce a contact resistance, the source electrode 24 and the drain electrode 25 are formed in a recess formed so as to extend through the AlGaN layer 23B, and are in direct contact with the channel region. The source electrode 24 and the drain electrode 25 need only be ohmic-connected to the channel region, and may be formed directly on the AlGaN layer 23B or formed on the AlGaN layer 23B with a contact layer interposed therebetween.

The control layer 26 is made of p-type AlGaN and has a thickness of 200 nm. The gate electrode 27 is made of palladium (Pd) or nickel (Ni) and is ohmic contact with the control layer 26. Providing the p-type control layer 26 enables the HFET 21 to be operated in a normally off mode. If normally-off operation is not required, the control layer 26 can be omitted and a normal Schottky electrode can be provided as the gate electrode 27.

The drain electrode 25 and the cathode 12 are electrically connected to each other through a drain via plug 31. The source electrode 24 and the anode 13 are electrically connected to each other through a source via plug 32. The source via plug 32 is insulated from the cathode 12 by an insulating film 33.

The back electrode 14 in ohmic contact with the anode 13 is formed on the second surface (back surface) of the semiconductor substrate 10. The back electrode 14 is electrically connected to the anode 13 of the diode 11, and is also electrically connected to the source electrode 24 of the HFET 21 through the source via plug 32. Accordingly, the source electrode 24 can be easily grounded from the back surface of the substrate, and adhesion between a chip and solder can be improved when a chip diced from the semiconductor device is solder-mounted on a lead frame. Note that the source via plug 32 may be directly connected to the back electrode 14. Alternatively, the source via plug 32 may be omitted and the source electrode 24 and the back electrode 14 may be connected to each other through a wiring. In this case, a source electrode pad is required, but the step of forming the source via plug 32 can be omitted. The back electrode 14 may be made of any material. For example, the back electrode 14 may be made of a layered film of chromium, nickel, and silver.

FIG. 2 shows an equivalent circuit of the semiconductor device of the first embodiment. The diode is connected antiparallel between the drain and source of the HFET. In other words, the cathode of the diode is connected to the drain side, and the anode of the diode is connected to the source side. Energy from an inductive load can therefore be consumed by the diode, whereby the avalanche resistance of the HFET can be improved. The diode is formed in the semiconductor substrate on which the HFET is formed. Therefore, the occupied area of the semiconductor device does not increase.

The semiconductor device of the first embodiment can be formed by approximately the same process as that of a normal HFET by using a semiconductor substrate having an n-type region and a p-type region formed in advance by impurity implantation. The drain via plug 31 and the source via plug 32 can also be formed by a known method.

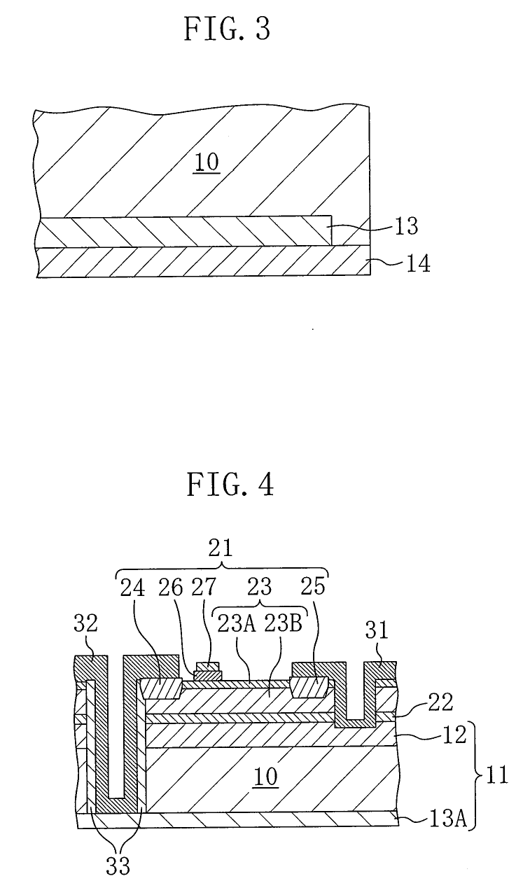

Note that, as shown in FIG. 3, it is preferable that the anode 13 that is a p-type region is not exposed to the side surface of the semiconductor substrate 10 when the semiconductor device of the first embodiment is diced into individual chips. This is because if a p-n junction is present at a cut surface of a semiconductor chip, the p-n junction is broken and a leakage current will increase therethrough.

In the first embodiment, the diode is a PIN diode. However, a PN junction diode having no intrinsic layer may be used. Alternatively, a Schottky barrier diode may be used as shown in FIG. 4. In this case, a Schottky electrode 13A formed on the second surface (back surface) of the semiconductor substrate 10 serves as an anode. Although a high breakdown voltage can be easily obtained by the PIN diode, the PIN diode has poor recovery characteristics. The use of a Schottky barrier diode as the diode 11 enables improvement in recovery characteristics. The Schottky electrode 13A may be made of any material. For example, the Schottky electrode 13A may be made of nickel, palladium, or gold. The Schottky electrode 13A functions as a back electrode that extends the source electrode 24 of the HFET 21 to the back surface of the substrate.

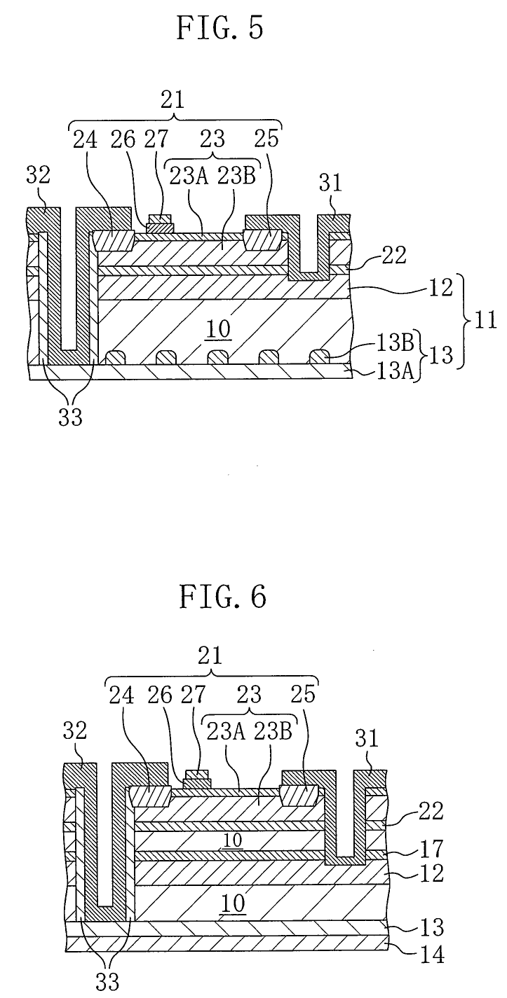

As shown in FIG. 5, the diode may be an MPS (Merged PIN and Schottky barrier) diode. In this case, a plurality of p-type regions 13B formed spaced apart from each other on the second surface side of the semiconductor substrate 10 and a Schottky electrode 13A formed on the second surface side of the semiconductor substrate 10 serve as the anode 13. The MPS diode has advantages of both a Schottky barrier diode and a PIN diode. The MPS diode is therefore a diode having a high breakdown voltage and excellent recovery characteristics.

In the first embodiment, a reverse breakdown voltage of the diode needs to be equal to or lower than the breakdown voltage of the HFET. Since a counter electromotive force that is generated in the inductive load in an off state is clamped by the breakdown voltage of the diode, the HFET will be broken down unless the breakdown voltage of the HFET is higher than the clamped voltage. More specifically, for an HFET having a breakdown voltage of about 250 V, the reverse breakdown voltage of the diode may be about 200 V.

### First Modification of First Embodiment

Hereinafter, a first modification of the first embodiment will be described with reference to the figures. FIG. 6 shows a cross-sectional structure of a semiconductor device according to the first modification of the first embodiment. In FIG. 6, the same elements as those of FIG. 1 are denoted by the same reference numerals and characters, and description thereof will be omitted.

The semiconductor device of the first modification has a diffusion prevention layer 17 formed between a cathode 12 that is an n-type region and a semiconductor layer laminate 23. The diffusion prevention layer 17 is made of silicon oxide (SiO₂) or the like and prevents diffusion of a group-III element contained in a nitride semiconductor. Ga or the like that is a group-III element functions as p-type impurities to silicon. Therefore, if Ga diffuses into the cathode 12 that is an n-type region, the cathode 12 may turn into a p-type region, degrading diode characteristics. Forming the diffusion prevention layer 17 prevents degradation of the diode resulting from the n-type region turning into a p-type region.

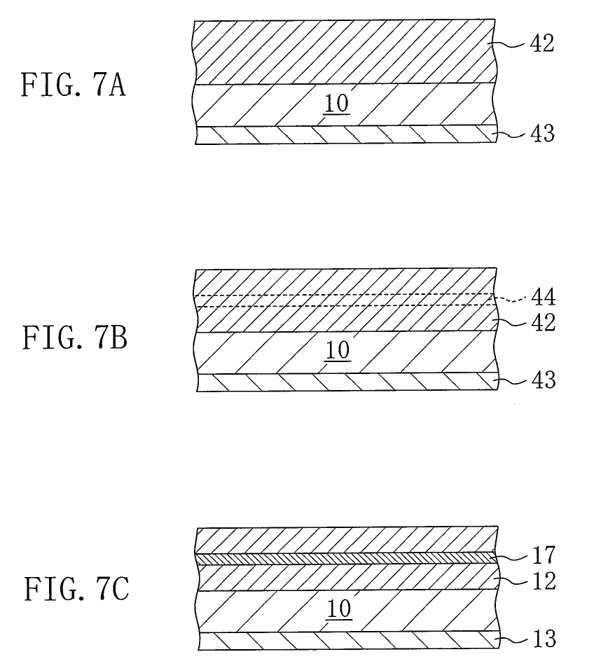

A manufacturing method of the semiconductor device according to the first modification will now be described with reference to the figures. FIGS. 7A through 7C sequentially show the steps of the manufacturing method of the semiconductor device according to the first modification.

First, as shown in FIG. 7A, n-type impurities are implanted from the first surface side of a semiconductor substrate 10, a silicon substrate, to form an n-type region 42 that will serve as a cathode of a diode. P-type impurities are also implanted from the second surface side of the semiconductor substrate 10 to form a p-type region 43 that will serve as an anode of the diode.

As shown in FIG. 7B, oxygen ions 44 are then implanted from the first surface side. The oxygen ions are implanted to a depth shallower than the n-type region 42.

As shown in FIG. 7C, the semiconductor substrate 10 is then annealed at a high temperature of about 1,000° C. to about 1,350° C. to form a diffusion prevention layer 17 of silicon oxide at a predetermined depth. This annealing process can also eliminate defects generated at the surface of the semiconductor substrate 10 by the ion implantation. The semiconductor substrate 10 having a cathode 12 formed on the element formation surface side, the diffusion prevention layer 17 formed between the cathode 12 and the element formation surface, and an anode 13 formed on the back surface side is thus obtained.

Although not shown in the figure, an HFET can then be formed on the semiconductor substrate 10 by a known method.

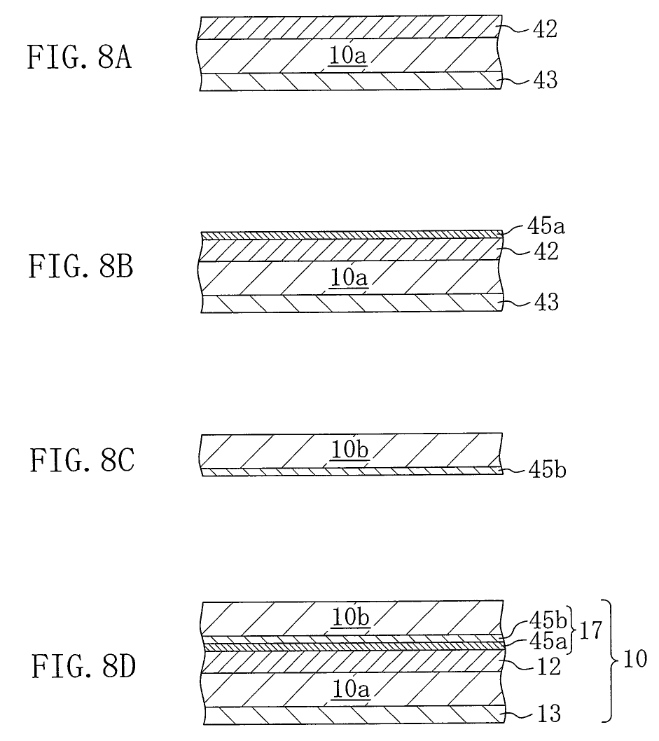

The semiconductor substrate 10 may be formed by a bonding method as described below. FIGS. 8A through 8D sequentially show the steps of the manufacturing method of the semiconductor substrate 10 by the bonding method.

First, as shown in FIG. 8A, n-type impurities are implanted from the first surface side of a lower substrate 10a, a silicon substrate, to form an n-type region 42 that will serve as a cathode of a diode. P-type impurities are also implanted from the second surface side of the lower substrate 10a to form a p-type region 43 that will serve as an anode of the diode.

As shown in FIG. 8B, the first surface of the lower substrate 10a is then oxidized to form a first oxide film layer 45a.

As shown in FIG. 8C, a surface opposite to an element formation surface of an upper substrate 10b, a silicon substrate, is also oxidized to form a second oxide film layer 45b.

As shown in FIG. 8D, heat treatment is then performed with the first oxide film layer 45a and the second oxide film layer 45b in close contact with each other to bond the lower substrate 10a and the upper substrate 10b. A semiconductor substrate 10 having a cathode 12 formed on the element formation surface side, a diffusion prevention layer 17 formed between the cathode 12 and the element formation surface, and an anode 13 formed on the back surface side is thus obtained.

Although not shown in the figure, an HFET can then be formed on the semiconductor substrate 10 by a known method.

Formation of the p-type region 43 can be omitted in the case of forming a Schottky barrier diode. An MPS diode may be formed by selectively implanting p-type impurities.

### Second Modification of First Embodiment

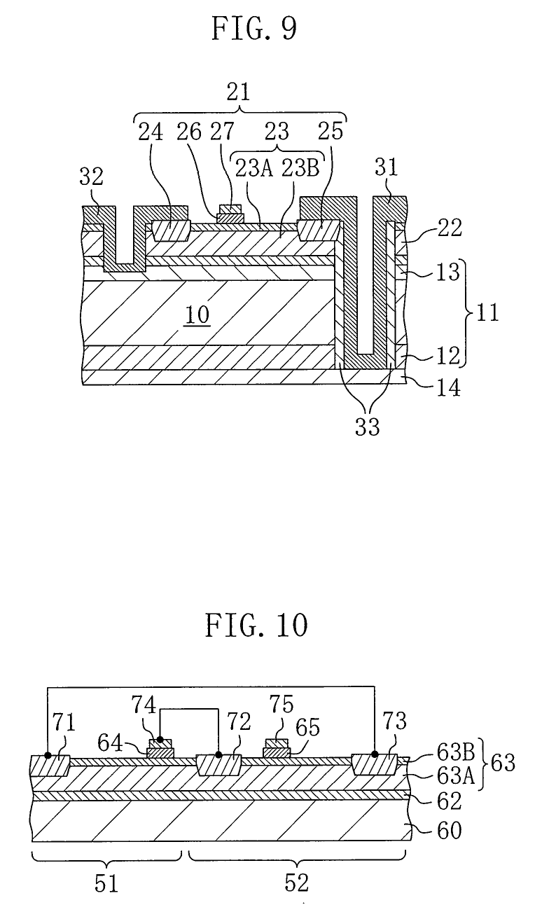

Hereinafter, a second modification of the first embodiment will be described with reference to the figures. FIG. 9 shows a cross-sectional structure of a semiconductor device according to the second modification of the first embodiment. In FIG. 9, the same elements as those of FIG. 1 are denoted by the same reference numerals and characters, and description thereof will be omitted. As shown in FIG. 9, in the semiconductor device of the second modification, a second surface of a semiconductor substrate 10 is an element formation surface and an HFET 21 is formed on the second surface. In this case, since a p-type region is formed on the HFET side, Ga diffusion from a nitride semiconductor layer into the semiconductor substrate would not cause any problems.

A Schottky barrier diode may be formed instead of a PIN diode. In this case, a source via plug 32 can be formed so as to form a Schottky junction with the semiconductor substrate 10 and can be used as a Schottky electrode.

Although a silicon substrate is used in the first embodiment and the modifications thereof, any substrate may be used as long as a diode can be formed and a semiconductor layer laminate made of a nitride semiconductor can be formed. For example, instead of a silicon (Si) substrate, a silicon carbide (SiC) substrate, a gallium nitride (GaN) substrate or the like may be used.

Note that forming the diffusion prevention layer as shown in the first modification is effective not only for a silicon substrate but for a silicon carbide substrate.

### Second Embodiment

Hereinafter, a second embodiment of the present invention will be described with reference to the figures. FIG. 10 shows a cross-sectional structure of a semiconductor device according to the second embodiment. As shown in FIG. 10, the semiconductor device of the second embodiment includes a diode 51 and an HFET 52 that are formed in a semiconductor layer laminate 63.

The semiconductor layer laminate 63 is formed on a substrate 60 with a buffer layer 62 interposed therebetween. The semiconductor layer laminate 63 has an undoped GaN layer 63A and an undoped AlGaN layer 63B that are formed sequentially from bottom.

A first electrode 71, a second electrode 72, and a third electrode 73 are formed spaced apart from each other in an upper portion of the semiconductor layer laminate 63. A fourth electrode 74 is formed between the first electrode 71 and the second electrode 72 on the semiconductor layer laminate 63 with a first p-type layer 64 interposed therebetween. A fifth electrode 75 is formed between the second electrode 72 and the third electrode 73 on the semiconductor layer laminate 63 with a second p-type layer 65 interposed therebetween. The first p-type layer 64 and the second p-type layer 65 are made of p-type AlGaN.

A PN junction diode is formed between the first p-type layer 64 and a two-dimensional electron gas formed at a hetero junction interface of the semiconductor layer laminate 63. The diode 51 having the first electrode 71 as a cathode electrode and the fourth electrode 74 as an anode electrode is thus formed.

Moreover, the HFET 52 having the second electrode 72 as a source electrode, the third electrode 73 as a drain electrode, and the fifth electrode 75 as a gate electrode is thus formed.

The first electrode 71 and the third electrode 73 are electrically connected to each other, and the second electrode 72 and the fourth electrode 74 are electrically connected to each other. Accordingly, a semiconductor device having the diode connected antiparallel between the source and drain of the HFET 52 can be implemented.

In the second embodiment, the diode 51 and the HFET 52 are formed in the semiconductor layer laminate 63. Therefore, the semiconductor device has a larger occupied area than in the case where a diode is formed in a semiconductor substrate. However, the HFET 52 and the diode 51 are formed integrally and increase in area is small. Moreover, since the diode 51 is also made of a nitride semiconductor, a high breakdown voltage, high speed diode can be implemented.

The first electrode 71, the second electrode 72, and the third electrode 73 are a laminate of titanium (Ti) and aluminum (Al), and are ohmic-connected to a channel region. In the second embodiment, in order to reduce a contact resistance, the first electrode 71, the second electrode 72, and the third electrode 73 are formed in a recess formed so as to extend through the AlGaN layer 63B, and are in direct contact with the channel region.

The second p-type layer 65 is provided in order to obtain a normally-off HFET 52. In order to obtain a normally-on HFET 52, the second p-type layer 65 can be omitted and the fifth electrode 75 can be formed as a normal Schottky electrode.

In the second embodiment, the substrate may be made of any material as long as the semiconductor layer laminate can be formed. For example, a semiconductor substrate such as silicon, silicon carbide, or gallium nitride or an insulating substrate such as sapphire may be used.

As has been described above, the nitride semiconductor device of the present invention can implement a nitride semiconductor device having a high avalanche resistance while suppressing increase in the number of parts and increase in occupied area caused by externally providing a diode. The nitride semiconductor device of the present invention is therefore useful as, for example, a nitride semiconductor device for use in a power supply circuit or the like.

The description of the embodiments of the present invention is given above for the understanding of the present invention. It will be understood that the invention is not limited to the particular embodiments described herein, but is capable of various modifications, rearrangements, and substitutions as will now become apparent to those skilled in the art without departing from the scope of the invention. Therefore, it is intended that the following claims cover all such modifications and changes as fall within the true spirit and scope of the invention.

1. A semiconductor device, comprising:
a semiconductor substrate;
a diode having a cathode formed on a first surface side of the semiconductor substrate and an anode formed on a second surface side of the semiconductor substrate; and
a transistor formed over the semiconductor substrate, wherein
the transistor includes a semiconductor layer laminate including a first nitride semiconductor layer and a second nitride semiconductor layer that are formed sequentially from the semiconductor substrate side, the second nitride semiconductor layer has a wider bandgap than that of the first nitride semiconductor layer, the transistor further includes a source electrode and a drain electrode that are formed spaced apart from each other over the semiconductor layer laminate, and a gate electrode formed between the source electrode and the drain electrode, the source electrode is electrically connected to the anode, and the drain electrode is electrically connected to the cathode.

2. The semiconductor device according to claim 1, wherein the cathode is an n-type region formed on the first surface side of the semiconductor substrate, and the anode is a p-type region formed on the second surface side of the semiconductor substrate.

3. The semiconductor device according to claim 2, wherein the p-type region is formed at a distance from a side edge portion of the semiconductor substrate.

4. The semiconductor device according to claim 1, wherein the cathode is an n-type region formed on the first surface side of the semiconductor substrate, and the anode is a Schottky electrode formed on the second surface side of the semiconductor substrate.

5. The semiconductor device according to claim 4, wherein the transistor is formed on the first surface and the Schottky electrode is a back electrode.

6. The semiconductor device according to claim 1, wherein the cathode is an n-type region formed on the first surface side of the semiconductor substrate, and the anode is formed by a Schottky electrode formed on the second surface side of the semiconductor substrate and a plurality of p-type regions formed spaced apart from each other on the second surface side of the semiconductor substrate.

7. The semiconductor device according to claim 1, further comprising a back electrode formed on the second surface of the semiconductor substrate, wherein the transistor is formed over the first surface of the semiconductor substrate.

8. The semiconductor device according to claim 1, further comprising a back electrode formed on the first surface of the semiconductor substrate, wherein the transistor is formed over the second surface of the semiconductor substrate.

9. The semiconductor device according to claim 1, further comprising a diffusion prevention layer formed on the first surface of the semiconductor substrate for preventing diffusion of a group-III element contained in the semiconductor layer laminate, wherein the cathode is an n-type region formed below the diffusion prevention layer.

10. The semiconductor device according to claim 1, further comprising: a drain via plug connecting the drain electrode and the cathode to each other; and a source via plug connecting the source electrode and the anode to each other.

11. The semiconductor device according to claim 1, wherein the semiconductor substrate is made of silicon, silicon carbide, or gallium nitride.

12. A semiconductor device, comprising:
a semiconductor layer laminate including a first nitride semiconductor layer formed over a substrate and a second nitride semiconductor layer formed on the first nitride semiconductor layer and having a wider bandgap than that of the first nitride semiconductor layer;
a cathode electrode, a source electrode, and a drain electrode that are formed spaced apart from each other over the semiconductor layer laminate;
a gate electrode formed between the source electrode and the drain electrode;
a first p-type semiconductor layer formed between the cathode electrode and the source electrode; and
an anode electrode formed on the first p-type semiconductor layer, wherein
the source electrode and the anode electrode are electrically connected to each other, and
the drain electrode and the cathode electrode are electrically connected to each other.

13. The semiconductor device according to claim 1, further comprising a second p-type semiconductor layer formed between the gate electrode and the semiconductor layer laminate.

14. A method for manufacturing a semiconductor device, comprising the steps of:
(a) preparing a semiconductor substrate having on a first surface side thereof an n-type region that will serve as a cathode of a diode, and having a diffusion prevention layer between the n-type region and the first surface;
(b) forming an anode of the diode on a second surface side of the semiconductor substrate;
(c) forming over the first surface of the semiconductor substrate a nitride transistor having a channel region in which electrons travel in a direction parallel to the first surface and having a source electrode, a drain electrode, and a gate electrode; and
(d) forming a drain via plug electrically connecting the drain electrode and the n-type region to each other; and
(e) electrically connecting the source electrode and the anode to each other.

15. The method according to claim 14, wherein the step (a) includes the steps of (a1) forming the n-type region by implanting n-type impurities to the first surface side of the semiconductor substrate, and (a2) forming a diffusion prevention layer made of an oxide film in an upper portion of the n-type region by first implanting oxygen ions in the upper portion of the n-type region and then performing heat treatment.

16. The method according to claim 14, wherein the step (a) includes the steps of (a1) forming the n-type region by implanting n-type impurities to a first surface side of a lower substrate, (a2) forming a first oxide film on the first surface of the lower substrate after the step (a1), (a3) forming a second oxide film on a first surface side of an upper substrate, and (a4) forming the diffusion prevention layer by bonding the first oxide film and the second oxide film to each other.

17. The method according to claim 14, wherein the step (b) is a step of forming the anode by implanting p-type impurities to the second surface side of the semiconductor substrate.

18. The method according to claim 17, wherein the anode is formed before formation of the impurity diffusion layer.

19. The method according to claim 14, wherein the step (b) is a step of forming a Schottky electrode on the second surface side of the semiconductor substrate.

20. The method according to claim 14, wherein the step (e) is the step of forming a source via plug electrically connecting the source electrode and the anode to each other.
